(19) United States
(12) Patent Application Publication
(10) Pub. No.: US 2013/0286559 A1
(43) Pub. Date: Oct. 31, 2013

(54) ELECTRONIC DEVICE WITH INFRARED WINDOW

(71) Applicants: TING-TING ZHAO, Shenzhen City (CN); HE-LI WANG, Shenzhen City (CN)

(72) Inventors: TING-TING ZHAO, Shenzhen City (CN); HE-LI WANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/570,264

(22) Filed: Aug. 9, 2012

(30) Foreign Application Priority Data
Apr. 28, 2012 (CN) 201210128487.2

(51) Int. Cl. H05K 5/03

(52) U.S. Cl. 361/679.01

(57) ABSTRACT

An electronic device includes an upper cover, a lower cover, and a cover. An infrared window is defined in the edge of the lower cover for receiving the cover. The cover includes a main body, a pair of arms each having a first end connected to the main body and an opposite second end, a pair of first blocks protruding outwardly from the second ends of the arms, and a pair of second blocks protruding from the first ends of the arms. A pair of latching members protrude from an inner surface of the lower cover and are arranged at opposite sides of the infrared window. Each latching member includes a hook formed at an end thereof. The hook engages with the first blocks, and the second blocks engage with the edge of the inner sides of the infrared window, thereby securing the cover to the lower cover.

### BACKGROUND

1. Technical Field

The present disclosure relates to electronic devices, and particularly, to an electronic device with infrared window.

2. Description of the Related Art

Electronic devices such as televisions and digital photo frames usually include an infrared receiver. An infrared window is formed in a housing of the electronic devices to allow infrared signals to pass and a cover is used to cover the infrared window. There are many connection techniques for connecting the cover to the housing. However, an electronic device with a new of connection technique for connecting the cover to the housing is still needed.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an isometric view of an electronic device with infrared window in accordance with an exemplary embodiment.

FIG. 2 is an exploded, isometric view of the electronic device in FIG. 1.

FIG. 3 is a partial, isometric view of the electronic device in FIG. 2.

FIG. 4 is a partial, assembled view of the electronic device in FIG. 1.

### DETAILED DESCRIPTION

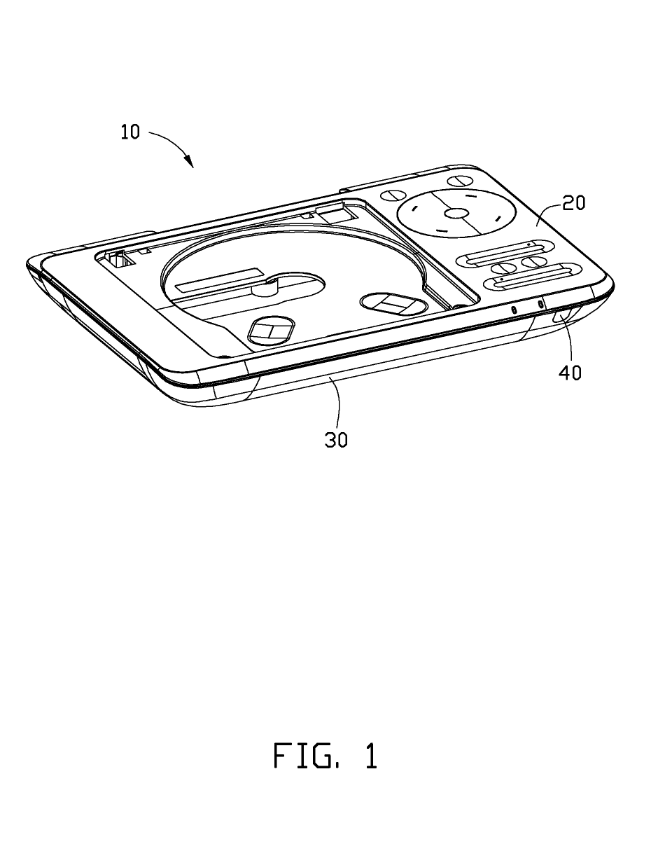

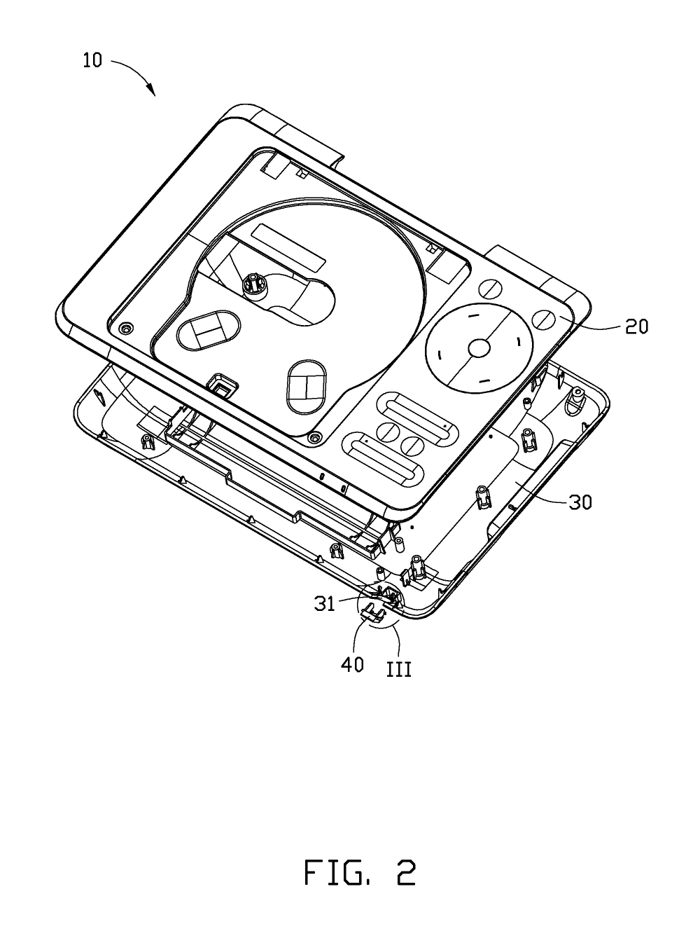

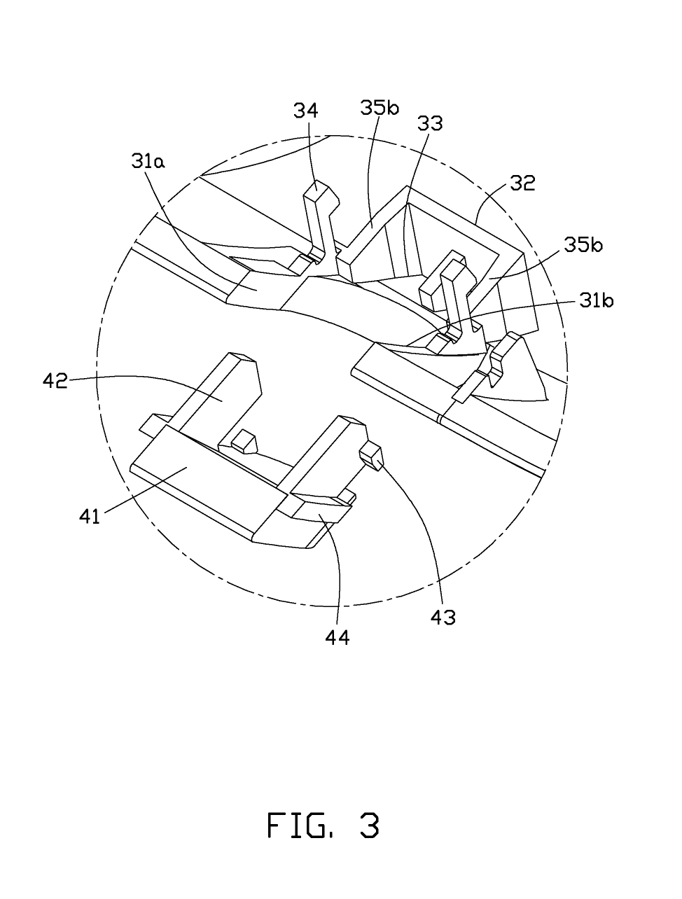

Referring to FIGS. 1-3, an embodiment of an electronic device 10 is shown. The electronic device 10, for example, a DVD player, includes an upper cover 20 and a lower cover 30. An infrared window 31 is defined in the edge of the lower cover 30. A cover 40 engaged in the infrared window 31 for covering the infrared window 31. The cover 40 is comprised of elastic material and deformable. An infrared sensor (not shown) is received in the lower cover and aligned with the infrared window 31.

The cover 40 includes a main body 41, a pair of arms 42 each having a first end connected to the main body 41 and an opposite second end, a pair of first blocks 43 respectively protruding outwardly from the second ends of the arms 42, and a pair of second blocks 44. Each of the second blocks 44 protrudes from the first end of one arm 42 where one block 43 locates, at a position where the main body 41 and the arm 42 joins. In the embodiment, the first blocks 43 are substantially perpendicular to the second blocks 44.

A stop wall 32 and two sidewalls 35a and 35b protrude from the inner side of the lower cover 30. The stop wall 32 and the sidewalls 35a and 35b cooperatively define a receiving cavity 33 adjacent to the infrared window 31. The receiving cavity 33 is configured for receiving an IR light-sensing element (not shown). A pair of latching members 34 protrude from the inner side of the lower cover 30 and are arranged at opposite edges 31a and 31b of the infrared window 30. Each latching member 34 includes a hook 340 extending towards the stop wall 32.

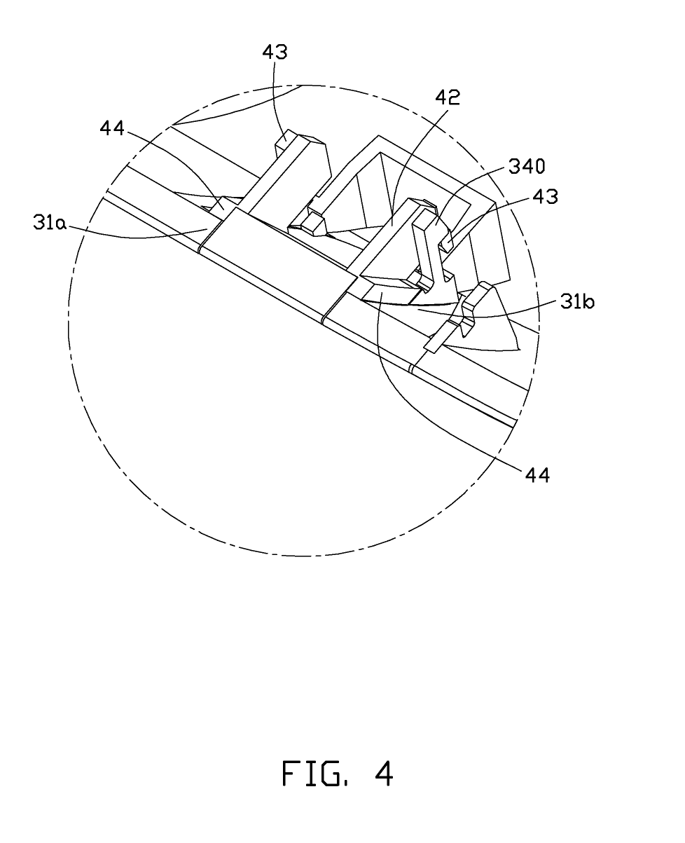

Referring to FIG. 4, the main body 41 is fitted in the infrared window 31, the hooks 340 engage with the first blocks 43, and the second blocks 44 engage with the inner surface of the lower cover 30, thereby securing the cover 40 to the lower cover 30.

It is understood that the present disclosure may be embodied in other forms without departing from the spirit thereof. Thus, the present examples and embodiments are to be considered in all respects as illustrative and not restrictive, and the disclosure is not to be limited to the details given herein.

What is claimed is:

1. An electronic device comprising:
an upper cover;
a lower cover comprising an edge and an infrared window defined in the edge thereof, a pair of latching members protruding from an inner surface of the lower cover and arranged at opposite sides of the infrared window, each latching member comprising a hook formed at an end thereof;
a cover engaged in the infrared window for covering the infrared window, the cover comprising a main body, a pair of arms each having a first end connected to the main body and an opposite second end, a pair of first blocks respectively protruding outwardly from the second ends of the arms, and a pair of second blocks respectively protruding from the first ends of the arms; the hooks engaging with the first blocks, and the second blocks engaging with the inner surface of the lower cover, thereby securing the cover to the lower cover.

2. The electronic device as recited in claim 1, wherein the first blocks are substantially perpendicular to the second blocks respectively.

3. The electronic device as recited in claim 1, further comprising a stop wall and two sidewalls protrude from the inner side of the lower cover, the stop wall, and the sidewalls cooperatively defining a receiving cavity adjacent to the infrared window, the receiving cavity configured for receiving an IR light-sensing element.

4. The electronic device as recited in claim 1, wherein the cover is comprised of elastic material and deformable.
